(19) United States
(12) Patent Application Publication
(10) Pub. No.: US 2023/0257868 A1
(43) Pub. Date: Aug. 17, 2023

(54) APPARATUS AND METHOD FOR FABRICATING PVD PEROVSKITE FILMS

(71) Applicant: Applied Materials, Inc., Santa Clara, CA (US)

(72) Inventors: Zihao YANG, Santa Clara, CA (US); Mingwei ZHU, San Jose, CA (US); Bharatwaj RAMAKRISHNAN, Sunnyvale, CA (US); Rongjun WANG, Dublin, CA (US); Robert Jan VISSER, Menlo Park, CA (US); Patibandla NAG, Santa Clara, CA (US)

(21) Appl. No.: 18/169,065

(22) Filed: Feb. 14, 2023

Related U.S. Application Data
(60) Provisional application No. 63/309,966, filed on Feb. 14, 2022.

(51) Int. Cl. C23C 14/34; C23C 14/58; C23C 14/54; C23C 14/08; G03F 7/00

(52) U.S. Cl. CPC C23C 14/3464; C23C 14/5806; C23C 14/541; C23C 14/082; C23C 14/086; C23C 14/085; C23C 14/5873; G03F 7/0035

(57) ABSTRACT

Embodiments described herein relate to a method of fabricating a perovskite film device. The method includes heating and degassing a substrate within a processing system; depositing a first perovskite film layer over a surface of the substrate using multi-cathode sputtering deposition within a processing chamber; depositing a second perovskite film layer over the first perovskite film layer using multi-cathode sputtering deposition within a processing chamber; and annealing the substrate with the first perovskite film layer and second perovskite film layer disposed thereon. The first perovskite film layer includes a first perovskite material. The second perovskite film layer includes a second perovskite material.

### CROSS-REFERENCE TO RELATED APPLICATIONS

This application claims benefit of U.S. Provisional Patent Application No. 63/309,966, filed Feb. 14, 2022, which is herein incorporated by reference in its entirety.

### BACKGROUND

### Field

Embodiments of the present disclosure generally relate to an apparatus and methods of depositing perovskite films. More specifically, embodiments described herein relate to deposition of perovskite films to create perovskite film devices.

### Description of the Related Art

Functional perovskite materials have attracted attention for many emerging logic and memory applications, such as ferroelectric random access memory (Fe-RAM) and resistive random access memory (Re-RAM), among other applications. Dielectric physical vapor deposition (PVD) using hafnium oxide, tantalum oxide, or aluminum oxide has been used for these applications in the past. However, the complex oxides of perovskite materials are more difficult to deposit due to the multiple elements in the perovskite material and the complicated crystal structures. This makes high volume manufacturing and production ready 300 mm deposition solutions for realizing high quality perovskite materials challenging.

Thus, improved perovskite PVD equipment and methods are needed in the art.

### SUMMARY

Embodiments of the present disclosure provide a method of fabricating a perovskite film device. The method includes heating and degassing a substrate within a processing system; depositing a perovskite film layer over a surface of the substrate using multi-cathode sputtering deposition within a processing chamber; and annealing the substrate with the perovskite film layer disposed thereon.

Embodiments of the present disclosure provide a method of fabricating a perovskite film device. The method includes heating and degassing a substrate within a processing system; depositing a first perovskite film layer over a surface of the substrate using multi-cathode sputtering deposition within a processing chamber; depositing a second perovskite film layer over the first perovskite film layer using multi-cathode sputtering deposition within a processing chamber; and annealing the substrate with the first perovskite film layer and second perovskite film layer disposed thereon. The first perovskite film layer includes a first perovskite material. The second perovskite film layer includes a second perovskite material.

Embodiments of the present disclosure provide a method of fabricating a perovskite film device. The method includes depositing a seed layer on a substrate; depositing a first perovskite film layer over the seed layer; depositing a second perovskite film layer over the first perovskite film layer; depositing a third perovskite film layer over the second perovskite film layer; annealing the substrate and perovskite film layers; lithographing and etching the second perovskite film layer and third perovskite film layer to form a top electrode and capacitor dielectric layer; and lithographing and etching the first perovskite film layer to form a bottom electrode.

### BRIEF DESCRIPTION OF THE DRAWINGS

So that the manner in which the above recited features of the present disclosure can be understood in detail, a more particular description of the disclosure may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic view of a cluster processing system according to embodiments.

FIG. 2 is a flow diagram of a method of fabricating a perovskite film device according to embodiments.

FIG. 3 is a schematic view of a multi-cathode processing chamber according to embodiments.

FIG. 4 is a flow diagram of a method of fabricating a perovskite film device according to embodiments.

FIG. 5A is a schematic side view of a perovskite film device according to embodiments.

FIG. 5B is a schematic top view of a perovskite film device according to embodiments.

FIG. 6 is a flow diagram of a method of fabricating a perovskite film device according to embodiments.

FIG. 7A-7D are schematic, cross-sectional views of a substrate during a method of fabricating a perovskite film device according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to an apparatus for and methods of depositing perovskite films. More specifically, embodiments described herein relate to deposition of perovskite films to form perovskite film devices. The method includes depositing a first perovskite film layer over a surface of the substrate using multi-cathode sputtering deposition within a processing chamber. A second perovskite film layer is deposited over the first perovskite film layer using multi-cathode sputtering deposition within a processing chamber. The first perovskite film layer and second perovskite film layer are annealed to promote crystallinity of the resultant perovskite film device. The first perovskite film layer includes a first perovskite material. The second perovskite film layer includes a second perovskite material.

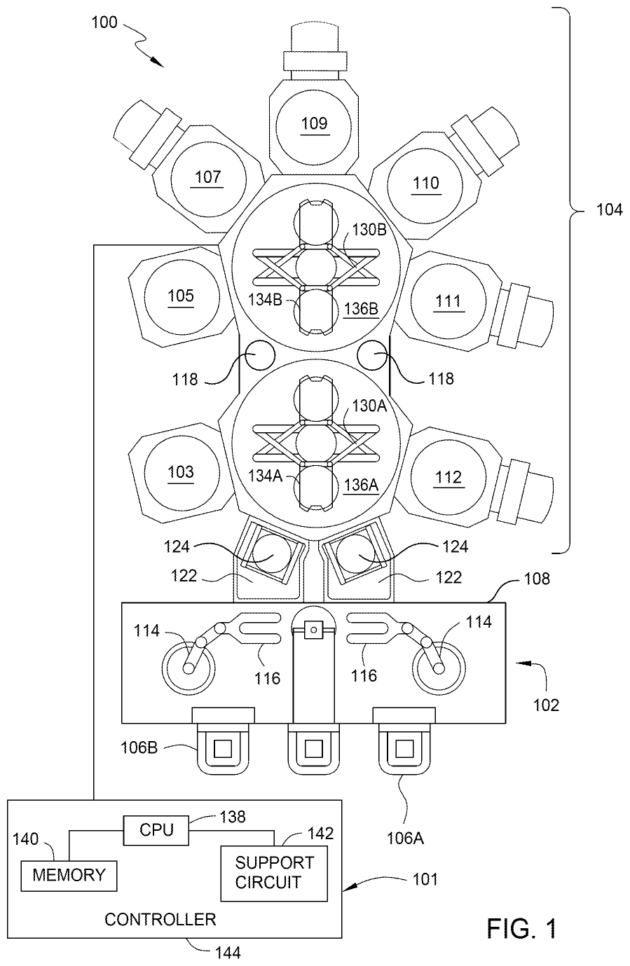

FIG. 1 is a schematic view of a cluster processing system 100. The cluster processing system 100 includes a processing platform 104, a factory interface 102, and a system controller 144. The processing platform 104 includes a plurality of processing chambers 103, 105, 107, 109, 110, 111, 112 and at least one load-lock chamber 122 that is coupled to a vacuum substrate transfer chamber. In one embodiment, the cluster processing system 100 includes one or more vacuum substrate transfer chambers, such as a first transfer chamber 136A and second transfer chamber 136B. In one embodiment, the cluster processing system 100 includes seven (7) processing chambers 103, 105, 107, 109, 110, 111, 112. In other embodiments, other amounts of processing chamber may be utilized. In one embodiment, the cluster processing system 100 includes two (2) load lock chambers 122. In other embodiments, more or less load lock chambers 122 may be utilized.

In one embodiment, the factory interface 102 comprises at least one docking station 108 and at least one factory interface robot 114 to facilitate transfer of substrates. The docking station 108 is configured to accept one or more front opening unified pods (FOUPs) 106A, 106B. In other embodiments, greater or less than two FOUPs may be utilized. The factory interface robot 114 having a first blade 116 disposed on one end of the robot 114 is configured to transfer the substrate from the factory interface 102 to the processing platform 104 for processing through the load lock chamber 122.

Each of the load lock chambers 122 have a first port coupled to the factory interface 102 and a second port coupled to the first transfer chamber 136A. The load lock chambers 122 are coupled to a pressure control system which pumps down and vents to load lock chambers 122 to facilitate passing the substrate between the vacuum environment of the first transfer chamber 136A and the substantially ambient (e.g., atmospheric) environment of the factory interface 102. The load lock chambers 122 are operable to heat and degas the substrate. By heating and degassing the substrate, impurities and contaminants are removed from the surface of the substrate.

In one embodiment of the cluster processing system 100, the cluster processing system 100 may include one or more processing chamber 103, 105, 107, 109, 110, 111, 112. The processing chambers 103, 105, 107, 109, 110, 111, 112 may be a deposition chambers (e.g., physical vapor deposition (PVD), chemical vapor deposition (CVD), atomic layer deposition (ALD) or other deposition chambers), annealing chambers (e.g., high-pressure annealing chamber, rapid thermal processing (RTP) chamber, or laser anneal chamber), etch chamber, cleaning chamber, pre-cleaning chamber, curing chamber, lithographic exposure chamber or other similar type of semiconductor processing chambers. In one embodiment, the processing chambers 103, 105, 107, 109, 110, 111, 112 may be a deposition chambers for sputtering films formed from perovskite materials. The cluster processing system 100 is capable of performing single layer perovskite film depositions or multiple layer perovskite film stack depositions within the processing chambers 103, 105, 107, 109, 110, 111, 112 to create perovskite film devices, such as ferroelectric perovskite capacitors. Perovskite materials are generally crystalline materials having a particular crystal structure ABX₃, wherein ‘A’ and ‘B’ are two ions, often of different sizes, and X is an ion (frequently an oxide) that bonds to both ions. The ‘A’ atoms are generally larger than the ‘B’ atoms.

In one embodiment, the processing chambers 103, 105, 107, 109, 110, 111, 112 may be additional material deposition chambers or other chambers that enable interface treatment, interfacial layer deposition, and multiple-layer film stack deposition. In some embodiments, one or more on-board metrology stations 118 are disposed within the processing platform 104 to facilitate measurement of the material properties of the perovskite films disposed on the substrate without removing the substrate from the processing platform 104. The cluster processing system 100 may also include facets for connecting additional chambers to the cluster processing system 100 for one or more of interface treatment, interfacial layer deposition, and multiple-layer film stack deposition. In some embodiments, one or more annealing chamber 124 may be disposed in the load lock chamber 122. The annealing chamber 124 may be one of a high-pressure annealing chamber, a RTP chamber, or laser anneal chamber.

The first transfer chamber 136A has a first vacuum robot 130A disposed therein. The vacuum robot 130A has a blade 134A capable of transferring substrates among the load lock chambers 122, the on-board metrology stations 118, and the processing chambers 103, 105, 107, 109, 110, 111, 112. In some embodiments, the processing platform 104 includes a second transfer chamber 136B. The second transfer chamber 136B has a second robot 130B disposed therein. The second robot 1306 has a second blade 1346 capable of transferring substrates among the on-board metrology stations 118, the processing chambers 105, 107, 109, 110, 111, and the first transfer chamber 136A.

The system controller 144 is coupled to the cluster processing system 100. The system controller 144, which may include a computing device 101 or be included within the computing device 101, controls the operation of the cluster processing system 100 using direct control of the process chambers 103, 105, 107, 109, 110, 111, 112 of the cluster processing system 100. Alternatively, the system controller 144 may control the computers (or controllers) associated with the process chambers 103, 105, 107, 109, 110, 111, 112 and the cluster processing system 100. In operation, the system controller 144 also enables data collection and feedback from the respective chambers to optimize performance of the cluster processing system 100.

The system controller 144 generally includes a central processing unit 138, a memory 140, and support circuits 142. The CPU 138 may be one or any form of a general purpose computer processor that can be used in an industrial setting. The support circuits 142 are conventionally coupled to the CPU 138 and may comprise a cache, clock circuits, input-output subsystems, power supplies, and the like. Processes may generally be stored in the memory 140 of the system controller 144 as a software routine that, when executed by the CPU 138, causes the process chamber to perform processes of the present disclosure. The software routines may also be stored and/or executed by a second controller (not shown) that is located remotely from the cluster processing system 100. Some or all of the methods of the present disclosure may also be performed in hardware. As such, the process may be implemented in software and executed using a computer system in hardware, e.g., as an application specific integrated circuit or other type of hardware embodiment, or as a combination of software and hardware.

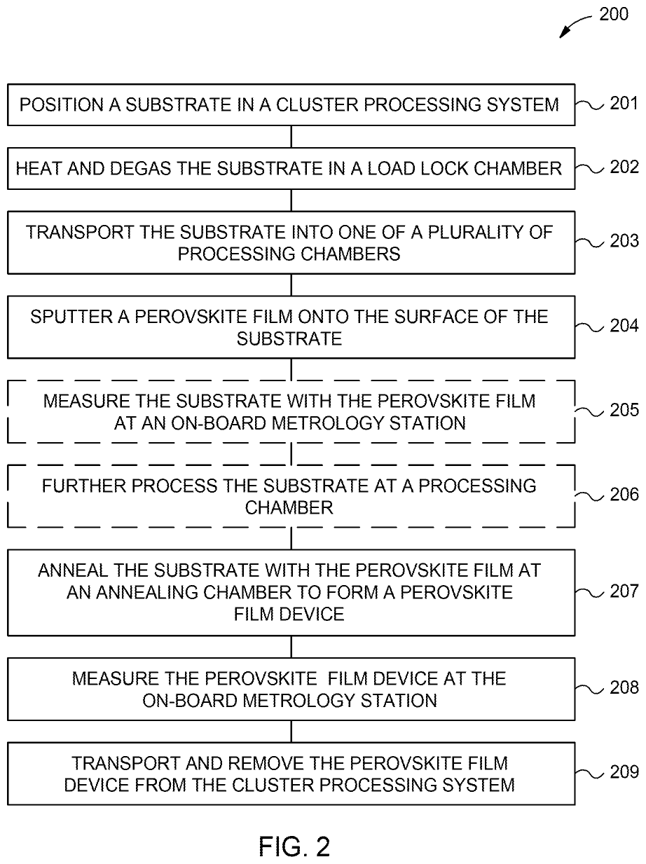

FIG. 2 is a flow diagram of a method 200 of fabricating a perovskite film device. At operation 201, a substrate is positioned in a cluster processing system 100 for processing. The substrate is positioned in one or more front opening unified pods (FOUPs) 106A, 106B. The substrate is transported from the one or more FOUPs 106A, 106B into a load lock chamber 122 of a processing platform 104 using a blade 116 disposed on one end of a robot 114.

At operation 202, the substrate is heated and degassed in a load lock chamber 122. By heating and degassing the substrate, impurities and contaminants may be removed from the load lock chamber 122 and the surface of the substrate. The impurities and contaminants can disrupt the perovskite film deposition process. Therefore, the removal of the impurities and contaminants helps to facilitate the perovskite film deposition process. In some embodiments, the load lock chamber 122 includes an annealing chamber 124. The annealing chamber 124 may be one of a high-pressure annealing chamber, a RTP chamber, or a laser anneal chamber. The annealing chamber 124 may be operable to heat the substrate to remove impurities and contaminations.

At operation 203, the substrate is transported into one of a plurality of processing chamber 103, 105, 107, 109, 110, 111, 112 for processing. The substrate is transported from the load lock chamber 122 to the processing chambers 103, 105, 107, 109, 110, 111, 112 through a first transfer chamber 136A or a second transfer chamber 136B. The first transfer chamber 136A includes a first vacuum robot 130A with a first blade 134A capable of transferring the substrates among the load lock chamber 122, the processing chambers 103, 105, 107, 109, 110, 111, 112, and an on-board metrology station 118. In some embodiments, the processing platform 104 includes the second transfer chamber 136B. The second transfer chamber 136B has a second robot 130B disposed therein. The second robot 1306 has a second blade 1346 capable of transferring substrates among the on-board metrology stations 118, the processing chambers 105, 107, 109, 110, 111, and the first transfer chamber 136A.

In some embodiments, the processing chambers 103, 105, 107, 109, 110, 111, 112 may be a deposition chamber (e.g., physical vapor deposition (PVD), chemical vapor deposition (CVD), atomic layer deposition (ALD) or other deposition chambers), annealing chambers (e.g., high-pressure annealing chamber, rapid thermal processing (RTP) chamber, or laser anneal chamber), etch chamber, cleaning chamber, pre-cleaning chamber, curing chamber, lithographic exposure chamber or other similar type of semiconductor processing chamber. In other embodiments, may be additional material deposition chambers or other chambers that enable interface treatment, interfacial layer deposition, and multiple-layer film stack deposition.

At operation 204, a perovskite film is sputtered onto a surface of the substrate within one of the processing chambers 103, 105, 107, 109, 110, 111, 112. The perovskite film is deposited using a method 400 or method 600, as will be described in further detail herein. In some embodiments, a single layer of a perovskite film is deposited on the surface of the substrate. In other embodiments, a multi-layer perovskite think film stack is deposited on the surface of the substrate. The multi-layer perovskite think film stack can have any integer number of layers deposited thereon.

At optional operation 205, the perovskite film disposed on the substrate is measured at the on-board metrology station 118. The substrate is transported to the on-board metrology station 118. The substrate is transported to the on-board metrology station 118 using the first blade 134A of the first vacuum robot or the second blade of the second vacuum robot, depending on which processing chamber 103, 105, 107, 109, 110, 111, 112 is in use. The on-board metrology station 118 monitors material properties of the perovskite film, such as the thickness and stoichiometry of the perovskite film.

At optional operation 206, the substrate is further processed at one of the processing chambers 103, 105, 107, 109, 110, 111, 112. The substrate is transported back to one of the processing chambers 103, 105, 107, 109, 110, 111, 112 using the first blade 134A of the first vacuum robot or the second blade of the second vacuum robot, depending on which processing chamber 103, 105, 107, 109, 110, 111, 112 is in use. In some embodiments, additional perovskite films may be deposited. In other embodiments, other types of deposition may occur (e.g., PVD, CVD, ALD). In still other embodiments, etching, cleaning, pre-cleaning, curing, lithography or other similar type of semiconductor processing may occur.

Optional operations 205-206 can be performed one or more times, depending on the desired perovskite film and desired resultant perovskite film device.

At operation 207, the perovskite film disposed on the substrate is annealed in the annealing chamber 124 to form a perovskite film device. The substrate is transported to the annealing chamber 124 in the load lock chamber 122 using the first blade 134A of the first vacuum robot or the second blade of the second vacuum robot, depending on which processing chamber 103, 105, 107, 109, 110, 111, 112 is in use. In one embodiment, the annealing occurs in controlled ambient conditions. The annealing is performed at a controlled temperature ramp rate within the load lock chamber 122. By annealing the perovskite film disposed on the substrate, the crystallinity of the perovskite film device is promoted.

At operation 208, the perovskite film device is measured at the on-board metrology station 118. The substrate is transported to the on-board metrology station 118 using the first blade 134A of the first vacuum robot. The on-board metrology station 118 monitors the thickness and stoichiometry of the perovskite film device.

At operation 209, the perovskite film device is transported from the on-board metrology station 118 through the load lock chamber 122 to the one or more FOUPs 106A, 106B and removed from the cluster processing system 100. The perovskite film device is transported to the load lock chamber 122 using the first blade 134A of the first vacuum robot or the second blade of the second vacuum robot, depending on which processing chamber 103, 105, 107, 109, 110, 111, 112 is in use. The substrate is transported through the load lock chamber 122 to the one or more FOUPs 106A, 106B using the blade 116 disposed on one end of a robot 114.

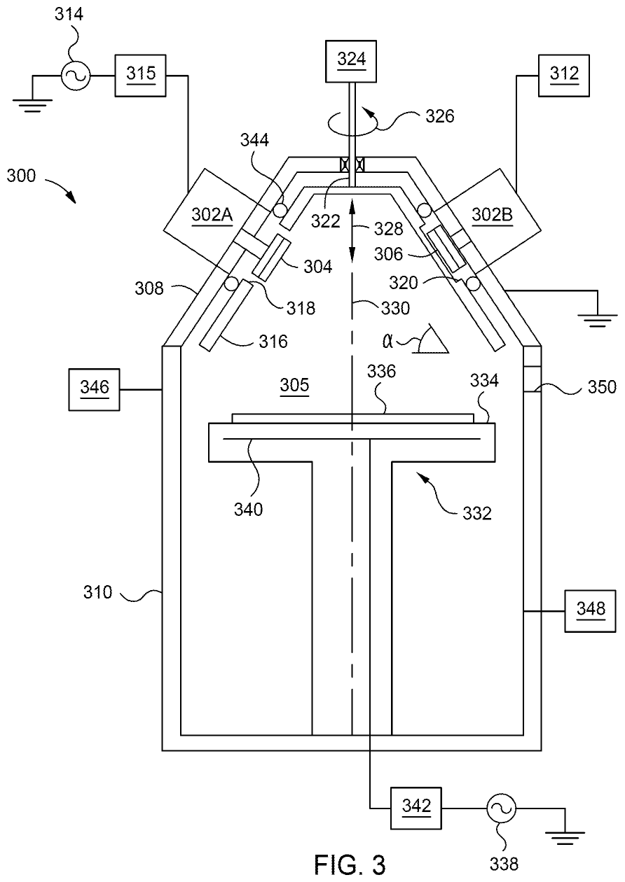

FIG. 3 is a schematic view of a multi-cathode processing chamber 300. The multi-cathode processing chamber 300 can be used in place of any of the one or more processing chambers 103, 105, 107, 109, 110, 111, and 112. The multi-cathode chamber 300 includes a plurality of cathodes having a corresponding plurality of targets attached to a chamber body adapter 308. In the illustrated embodiment, the multi-cathode chamber 300 has a first target 304 and a second target 306. In other embodiments, the multi-cathode chamber 300 may have more or less than 2 targets. In one embodiments, a first cathode is a RF cathode 302A corresponding to the first target 304. A second cathode is a DC (e.g., pulsed-DC or p-DC) cathode 302B corresponds to a second target 306. In some embodiments, the targets 304, 306 may be metal targets or dielectric targets. In some embodiments, the first target 304 may be formed of metals such as lanthanum (La), bismuth (Bi), iron (Fe), or a combination thereof. The second target 306 may be formed of metals such as strontium (Sr), ruthenium (Ru), lanthanum (La), manganese (Mn), or a combination of both. However, other metals and/or conductive metal oxides may alternatively be used. The processing chamber includes a substrate support 332 having a support surface 334 to support a substrate 336. The process chamber 300 includes an opening 350 (e.g., a slit valve) through which an end effector may extend to place the substrate 336 onto lift pins for lowering the substrate 336 onto the support surface 334.

Each target 304, 306 is disposed at a predetermined angle a with respect to the support surface 334. In some embodiments, the angle a with respect to the support surface 334. In some embodiments, the angle a may be from about 0° to about 50°. The substrate support 332 includes a biasing source 338 coupled to a bias electrode 340 disposed in the substrate support 332 via a matching network 342. The biasing electrode 340 applies a potential to the substrate in order to create a potential differential between the RF cathode 302A and DC cathode 302B, thus facilitating the deposition process. In some embodiment, the substrate support 332 further includes a heater and an electrostatic clamping/chucking (ESC) component. The heater is utilized to heat the substrate 336 during the processing of the substrate 336. Heating the substrate 336 promotes deposition of the perovskite materials onto the substrate 336. The ESC is used to chuck the substrate 336 to secure the substrate 336 to the substrate support 332 during deposition process. The chamber body adapter 308 is coupled to an upper portion of a chamber body 310 of the process chamber 300. The chamber body adapter 308 is grounded. In some embodiment, each target 304, 306 has an associated magnetron. A RF power source 314 is coupled to the RF cathode 302A via an RF matching network 315. Providing the correct amount of power to the RF capacitor has been a challenge in the past. This RF matching network 315 provides better RF power delivery to the RF cathode 302A during perovskite film deposition. Using the RF matching network 315, the impedance and capacitance of the RF power source 314 can be controlled to enable the correct amount of power to be delivered to the first target 304. A DC power source 312 is coupled to the DC cathode 302B. In some embodiments, the DC power source 312 is coupled to the DC cathode 302B via a DC matching network. The DC power source has a power range from about 400 Watts to about 1500 Watts.

A shield 316 is rotatably coupled to the chamber body adapter 308. Depending on the number of targets being used to sputter material at the same time, the rotating shield 316 can have one or more openings 318 to expose a corresponding one or more targets. The shield 316 limits or eliminates cross-contamination between the plurality of target. For example, in some embodiments where five cathodes are provided, the shield may include at least one opening 318 to expose the first target 304 to be sputtered to the substrate 336 and at least one pocket 320 to house the second target 306 to prevent sputtering. The shield 316 is rotationally coupled to the chamber body adapter 308 via a shaft 322.

An actuator 324 is coupled to the shaft 322 opposite the shield 316. The actuator 324 is configured to rotate the shield 316, as indicated by arrow 326, and move the shield 316 up or down along the central axis 330 of the process chamber 300, as indicated by arrow 328. The actuator 324 is further configured to rotate the substrate support 332. The rotation of the substrate support 332 allows for the material being deposited from the targets 304, 306 to be deposited evenly across the substrate 333. The substrate rotation speed can be adjusted using the actuator 324.

In some embodiments, the shield 316 may be provided with the pocket 320 to house a target not being sputtered. The pocket 320 prevents scattering of the sputtered target from being deposited on the target not being sputtered. Although such scattering is inevitable, the pocket 320 ensures that the scattering does not contaminate the sputtered surface of the non-sputtered target. As a result, contamination of the target not being sputtered is further reduced.

In some embodiments, the shield 316 has two openings and at least two target materials, allowing for multiple target material co-sputtering. For example, the process chamber includes at least three targets, the first target 304 and a third target (not shown) having the same material and the second target 306 having a different material. The shield 316 includes two openings 318 to expose the first target 304 and the third target. The exposure of the substrate 336 to two targets having the same material increased the amount of that material which is deposited on the substrate 336, allowing for greater control over the ratio and stoichiometry tuning of the elements being deposited. In another embodiment, the shield 316 includes two openings 318 to expose the first target 304 and the second target 306. The exposure of the substrate 336 to two targets having different materials allows for tuning of the stoichiometry of the perovskite film. By having the correct ratio and stoichiometry of elements, crystallinity of the resultant perovskite film can be promoted.

In some embodiments, the process chamber 300 includes a plurality of grounding rings 344 to provide improved grounding of the shield 316 to the grounded chamber body adapter 308 when the shield 316 is in the retracted position. The grounding rings 344 prevent the shield 316 from being charged by minimizing the energy between the plasma and the shield 316. As a result, the chances of the shield 316 being sputtered are further reduced.

In some embodiments, the process chamber 300 further includes a process gas supply 346 to supply a predetermined process gas to an interior volume 305 of the process chamber 300. The process chamber 300 may also include an exhaust pump 348 fluidly coupled to the interior volume 305 to exhaust the process gas from the process chamber 300. In some embodiments, the process gas supply may supply a process gas to the interior volume 305 after the targets 304, 306 have been sputtered. The process gas may include oxygen (O₂), argon (Ar), krypton (Kr), or neon (Ne). The process gas is used to pre-condition the process chamber for the deposition process.

The exhaust pump 348 is further configured to control to concentration and pressure of the process gas within the chamber. The exhaust pump 348 also allows for stoichiometric tuning by changing the concentration and pressure of the process gas within the interior volume 305 of the process chamber 300. Controlling the pressure within the process chamber 300 promotes the crystallinity of a perovskite material. The exhaust pump 348 monitors and adjusts the pressure within the process chamber 300 automatically in order to satisfy the pressure conditions required to promote the crystallinity of the perovskite material.

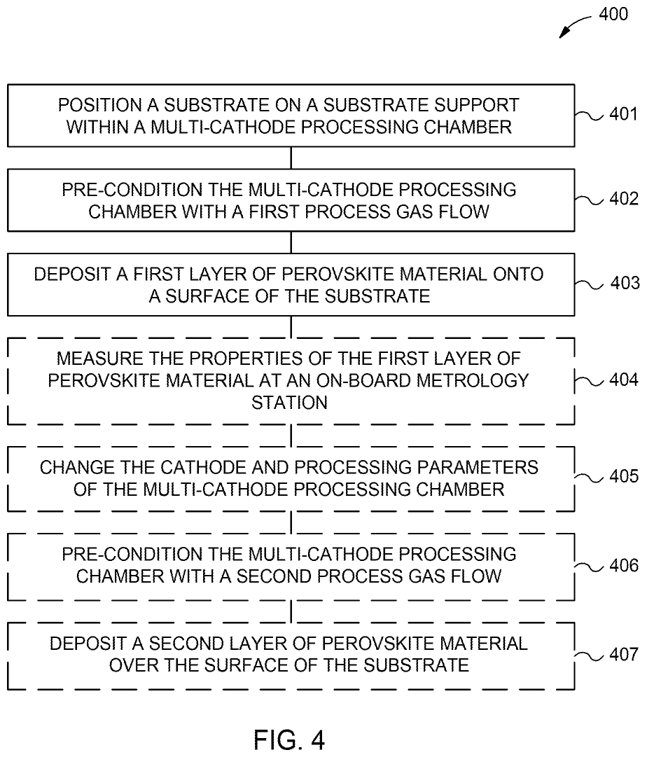

FIG. 4 is a flow diagram of a method 400 of fabricating a perovskite film according to embodiments. The method 400 may be performed at operation 204 in method 200.

At operation 401, a substrate 336 is positioned on a substrate support 332 within a multi-cathode processing chamber 300. The multi-cathode processing chamber 300 can be used in place of any of the one or more processing chambers 103, 105, 107, 109, 110, 111, and 112. The substrate 336 is transported into the multi-cathode processing chamber 300 using one of a first vacuum robot 130A with a first blade 134A in a first transfer chamber 136A or a second vacuum robot 130B with a second blade 134B in a second transfer chamber 136B. In one embodiment, the substrate 336 is chucked (e.g., positioned on, secured to) to the substrate support 332 using an electrostatic semiconductor clamping/chucking (ESC) component. In some embodiments, the substrate support 332 includes a heater to heat the substrate for processing. In some embodiments, the substrate support 332 is coupled to an actuator 324 to rotate the substrate support 332 and subsequently the substrate 336.

At operation 402, the multi-cathode processing chamber 300 is pre-conditioned using a first process gas flow. The process gas may include one of oxygen (O₂), argon (Ar), krypton (Kr), or neon (Ne). The process gas is pumped into an interior volume 305 of the multi-cathode processing chamber 300 via a process gas supply 346. An exhaust pump 348 is fluidly coupled to the multi-cathode processing chamber 300 to exhaust the process gas from the interior volume 305.

At operation 403, a first layer of perovskite material is deposited onto the surface of the substrate 336 with a first deposition gas flow. The first deposition gas flow includes the process gas, which may include one of oxygen (O₂), argon (Ar), krypton (Kr), or neon (Ne). The first deposition gas flow is from about 0.1 mTorr to about 5 mTorr. The first deposition gas flow has about 0% to about 10% oxygen by concentration. The perovskite material is disposed via sputtering deposition from one or more target, (e.g., a first target 304 and a second target 306). In one embodiment, the first target 304 is a coupled to an RF cathode 302A and the second target 306 is coupled to a DC/p-DC cathode 302B. In some embodiments, the targets 304, 306 may be metal targets or dielectric targets. In some embodiments, the first target 304 may be formed of metals such as lanthanum (La), bismuth (Bi), iron (Fe), or a combination thereof. The second target 306 may be formed of metals such as strontium (Sr), ruthenium (Ru), lanthanum (La), manganese (Mn), or a combination of both. However, other metals and/or conductive metal oxides may alternatively be used. In one embodiment, the first layer of perovskite material is a strontium ruthenium oxide or lanthanum strontium manganese oxide. In another embodiment, the first layer of perovskite material is a lanthanum bismuth iron oxide.

In one embodiment, the first layer of perovskite material is deposited using single target sputtering (e.g., the first target 304 or the second target 306). A shield 316 including an opening 318 is rotatably coupled to a chamber body adapter 308 of the multi-cathode processing chamber 300. The opening 318 can be selectively rotated using the actuator 324 between one or more targets, e.g., the first target 304 and the second target 306, to deposit the first layer of perovskite material. For example, as shown in FIG. 3, the opening 318 may be selectively rotated to the first target 304 to expose the first target 304 to the substrate 336, while the second target 306 is housed within a pocket 320 of the shield 316 and is not exposed to the substrate 336. The first target 304 being exposed to the substrate 336 via the opening 318 allows for the first target 304 to deposit (e.g., sputter) material onto the substrate 336, while the shield 316 prevents the second target 306 from depositing (e.g., sputtering) material on to the substrate 336.

In another embodiment, the first layer of perovskite material is deposited using multi-target sputtering with two or more targets (e.g., the first target 304 and the second target 306). The shield 316 may include two or more openings 318 that can be selectively rotated between two or more targets, e.g., first target 304, and second target 306. For example, the processing chamber may have three or more targets, e.g., first target 304, second target 306, and a third target (not shown). The shield 316 may be selectively rotated such that a first shield opening and a second shield opening expose the first target 304 and the second target 306 to the substrate, while the third target is housed within a pocket 320 of the shield 316 and is not exposed to the substrate. The first target 304 and second target 306 being exposed to the substrate 336 via the openings allows for the first target 304 and second target 306 to deposit (e.g., sputter) material onto the substrate 336, while the shield 316 prevents the third target from depositing (sputtering) material on to the substrate. In some embodiments, the co-sputtering technique may include one or more targets sputtering the same material. In other embodiments, the co-sputtering may include each target comprising a different material from the other targets. The ability to co-sputter two or more targets allows for greater control of the stoichiometry of the deposited perovskite film. The greater stoichiometric control over of the deposited perovskite film increases the crystallinity of the resultant perovskite film device. For example, a second target could be used to improve the overall composition across the entire substrate, e.g., if a particular element/molecule of the desired perovskite film is insufficiently deposited across the substrate, a co-sputtering target of that element/molecule may be utilized to increase the composition of the particular element. Additionally, if a particular element/molecule of the desired film is insufficiently deposited at a particular position across the substrate, a co-sputtering target of that element/molecule may be utilized to increase the composition of the element/molecule at the particular position of the substrate.

In some embodiments, during the single target or the multi-target sputtering, an actuator 324 may rotate the substrate support to promote even deposition of the targets 304, 306. The actuator 324 may rotate the substrate support from about 5 rpm to about 90 rpm.

At optional operation 404, the material properties of the first layer perovskite material may be measured in the on-board metrology station 118. The substrate 336 with a first layer of perovskite material disposed thereon may be transported to an on-board metrology station 118 within a processing platform 104 of a cluster processing system 100. In one embodiment, the processing platform 104 is a vacuum-tight processing platform. The on-board metrology station 118 may be used to monitor the thickness, stoichiometry, and/or crystallinity of the first layer of the perovskite material.

At optional operation 405, the cathode and processing parameters of the multi-cathode processing chamber 300 are changed. The change in the processing parameters of the processing chamber includes changing the process position (e.g., the height of the substrate support within the multi-cathode processing chamber 300), gas flow rate, and rotation speed of the substrate support.

At optional operation 406, the process chamber 300 is pre-conditioned with a second process gas flow. The process gas may include one of oxygen (O₂), argon (Ar), krypton (Kr), or neon (Ne). The process gas is pumped into the interior volume 305 of the multi-cathode processing chamber 300 via the process gas supply 346. An exhaust pump 348 is fluidly coupled to the multi-cathode processing chamber 300 to exhaust the process gas from the interior volume 305.

At an optional operation 407, a second layer of perovskite material is deposited with a second deposition gas flow. The second deposition gas flow includes the process gas, which may include one of oxygen (O₂), argon (Ar), krypton (Kr), or neon (Ne). The second deposition gas flow is from about 0.1 mTorr to about 5 mTorr. The second deposition gas flow has about 0% to about 10% oxygen by concentration. The second deposition gas flow, in some embodiments, is different from the first deposition gas flow. The perovskite material is disposed via sputtering deposition from one or more target, (e.g., the first target 304 and the second target 306). In one embodiment, the first target 304 is a coupled to the RF cathode 302A and the second target 306 is coupled to the DC/p-DC cathode 302B. In some embodiments, the targets 304, 306 may be metal targets or dielectric targets. In some embodiments, the first target 304 may be formed of metals such as lanthanum (La), bismuth (Bi), iron (Fe), or a combination thereof. The second target 306 may be formed of metals such as strontium (Sr), ruthenium (Ru), lanthanum (La), manganese (Mn), or a combination of both. However, other metals and/or conductive metal oxides may alternatively be used. In one embodiment, the second layer of perovskite material is a strontium ruthenium oxide or lanthanum strontium manganese oxide. In another embodiment, the second layer of perovskite material is a lanthanum bismuth iron oxide.

In one embodiment, the second layer of perovskite material is deposited using single target sputtering (e.g., the first target 304 or the second target 306). The shield 316 including the opening 318 is rotatably coupled to a chamber body adapter 308 of the multi-cathode processing chamber 300. The opening 318 can be selectively rotated using the actuator 324 between one or more targets, e.g., the first target 304 and the second target 306, to deposit the first layer of perovskite material. For example, as shown in FIG. 3, the opening 318 may be selectively rotated to the first target 304 to expose the first target 304 to the substrate 336, while the second target 306 is housed within a pocket 320 of the shield 316 and is not exposed to the substrate 336. The first target 304 being exposed to the substrate 336 via the opening 318 allows for the first target 304 to deposit (e.g., sputter) material onto the substrate 336, while the shield 316 prevents the second target 306 from depositing (e.g., sputtering) material on to the substrate 336. By using single target sputtering, system maintenance costs are decreased. In addition, the process drift of the targets and number of particles introduced to the film stack are minimized.

In another embodiment, the second layer of perovskite material is done using multi-target sputtering with two or more targets (e.g., the first target 304 and the second target 306). The shield 316 may include two or more openings 318 that can be selectively rotated between two or more targets, e.g., first target 304, and second target 306. For example, the multi-cathode processing chamber 300 may have three or more targets, e.g., first target 304, second target 306, and a third target (not shown). The shield 316 may be selectively rotated such that a first shield opening and a second shield opening expose the first target 304 and the second target 306 to the substrate 336, while the third target is housed within a pocket 320 of the shield 316 and is not exposed to the substrate 336. The first target 304 and second target 306 being exposed to the substrate 336 via the openings allows for the first target 304 and second target 306 to deposit (e.g., co-sputter) material onto the substrate 336, while the shield 316 prevents the third target from depositing (sputtering) material on to the substrate 336. In some embodiments, the co-sputtering technique may include one or more targets sputtering the same material. In other embodiments, the co-sputtering may include each target comprising a different material from the other targets. The ability to co-sputter two or more targets allows for greater control of the stoichiometry of the deposited perovskite film. The greater stoichiometric control over of the deposited perovskite film increases the crystallinity of the resultant perovskite film device. For example, a second target could be used to improve the overall composition across the entire substrate, e.g., if a particular element/molecule of the desired perovskite film is insufficiently deposited across the substrate, a co-sputtering target of that element/molecule may be utilized to increase the composition of the particular element. Additionally, if a particular element/molecule of the desired film is insufficiently deposited at a particular position across the substrate, a co-sputtering target of that element/molecule may be utilized to increase the composition of the element/molecule at the particular position of the substrate.

Optional operations 404-407 can be performed one or more times, depending on the desired number of perovskite film layers and desired resultant perovskite film device.

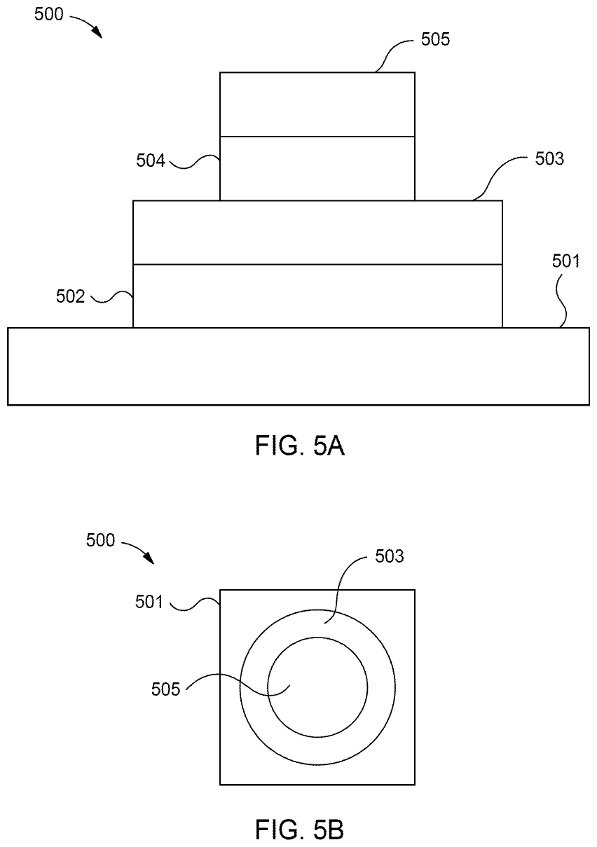

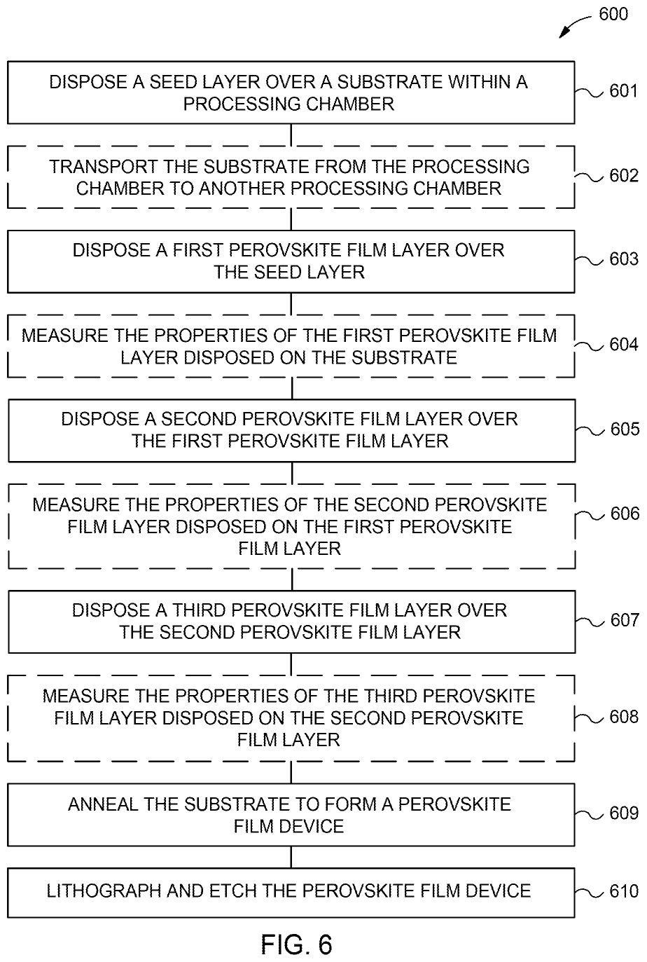

FIG. 5A is a schematic side view of a perovskite film device 500 according to embodiments. FIG. 5B is a schematic top view of a perovskite film device 500 according to embodiments. The perovskite film device 500 includes devices such as ferroelectric perovskite capacitors, piezoelectric micro-actuator, or magnetic sensors. A ferroelectric perovskite capacitor has ferroelectric properties that result in more efficient memory functions. The perovskite film device 500 includes a substrate 501, a seed layer 502, a first perovskite film layer 503, a second perovskite film layer 504, and a third perovskite film layer 505. In one embodiment, the substrate 501 can be a silicon substrate, a silicon germanium substrate, a complementary metal-oxide semiconductor (CMOS), glass, or sapphire. In one embodiment, the substrate 501 contains a plurality of transistors for use in a capacitor.

The seed layer 502 is disposed over the substrate 501. In one embodiment, the seed layer 502 comprises a material such as magnesium oxide (MgO), titanium nitride (TiN), SrTiO₃, or platinum (Pt). The seed layer 502 is configured to bridge between the substrate 501 and the perovskite film layers 503, 504, and 505, providing an electrical connection between the transistors within the substrate 501 and the perovskite film layers 503, 504, and 505. In some embodiments, the seed layer 502 may also help to promote the crystallinity of the perovskite film layers 503, 504, and 505.

The first perovskite film layer 503 is disposed over the seed layer 502. In one embodiment, the first perovskite film layer 503 is a strontium ruthenium oxide or lanthanum strontium manganese oxide.

The second perovskite film layer 504 is disposed over the first perovskite film layer 503. In one embodiment, the second perovskite film layer 504 is a lanthanum bismuth iron oxide.

The third perovskite film layer 505 is disposed over the first perovskite film layer 505. In one embodiment, the third perovskite film layer 505 is a strontium ruthenium oxide or lanthanum strontium manganese oxide. The first and third perovskite film layers 503, 505 are configured to promote crystallinity in the second perovskite film layer 504 to enhance the ferroelectric properties of the perovskite film layers 503, 504, and 505.

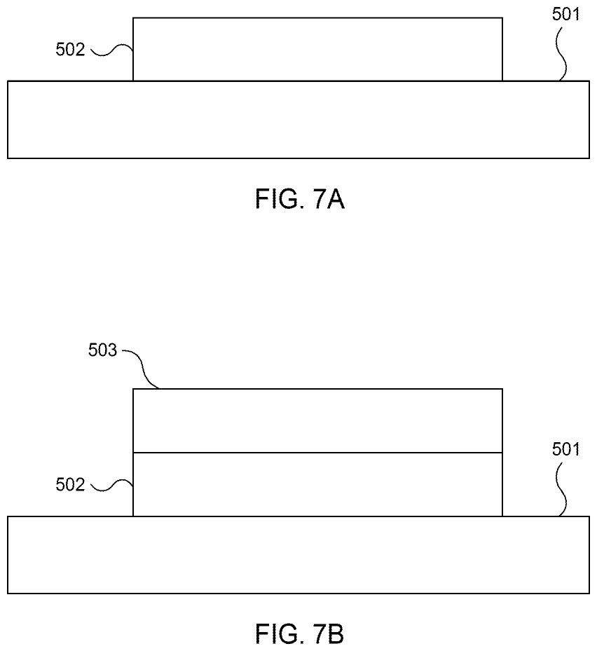

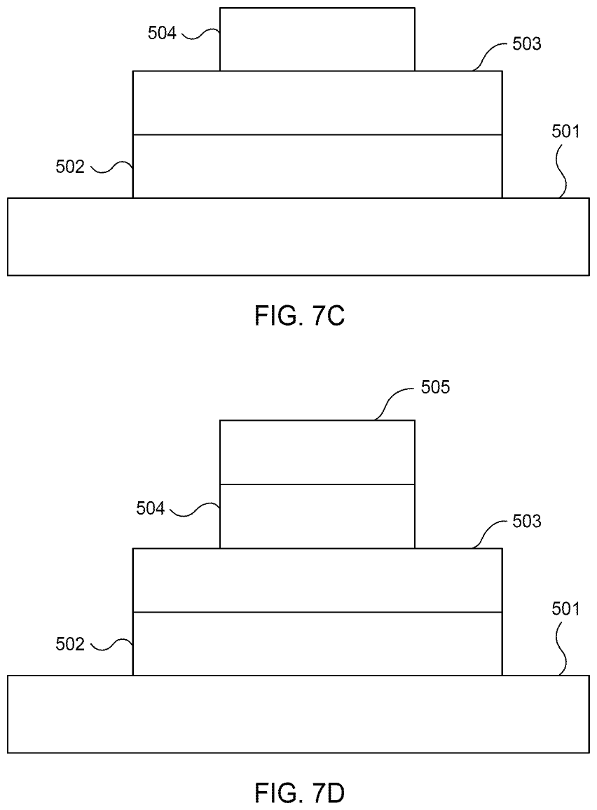

FIG. 6 is a flow diagram of a method of fabricating a perovskite film device 500. FIG. 7A-7D are schematic, cross-sectional views of a substrate 501 during a method of fabricating a perovskite film device 500. The method 600 may be performed at operation 204 in method 200.

At operation 601, a seed layer 502 is disposed over the substrate 501, as shown in FIG. 7A. The seed layer 502 is disposed over the substrate within a processing chamber such as multi-cathode processing chamber 300, which can be used in place of any of the one or more processing chambers 103, 105, 107, 109, 110, 111, and 112. The seed layer 502 is disposed over the substrate 501 using electroless plating, electrochemical deposition, PVD, plasma enhanced CVD (PECVD), CVD, ALD, or other deposition methods. The seed layer 502 comprises a material such as magnesium oxide (MgO), titanium nitride (TiN), SrTiO₃, or platinum (Pt). The seed layer 502 is configured to bridge between the substrate 501 and perovskite film layers 503, 504, and 505, providing an electrical connection between transistors within the substrate 501 and the perovskite film layers 503, 504, and 505. In some embodiments, the seed layer 502 may also help to promote the crystallinity of the perovskite film layers 503, 504, and 505.

At an optional operation 602, the substrate 501 with the seed layer 502 disposed thereon is transported from one of the processing chamber 103, 105, 107, 109, 110, 111, 112 to another of the processing chambers 103, 105, 107, 109, 110, 111, 112 to change the type of processing performed in the processing chamber. The substrate 501 may be transported from processing chamber 103, 105, 107, 109, 110, 111, 112 to the another processing chamber 103, 105, 107, 109, 110, 111, 112 using one of a first vacuum robot 130A with a first blade 134A in a first transfer chamber 136A or a second vacuum robot 130B with a second blade 134B in a second transfer chamber 136B of a cluster processing system 100.

At operation 603, a first perovskite film layer 503 is disposed over the seed layer 502 with a first deposition gas flow, as shown in FIG. 7B. The first deposition gas flow includes a process gas, which may include one of oxygen (O₂), argon (Ar), krypton (Kr), or neon (Ne). The first deposition gas flow is from about 0.1 mTorr to about 5 mTorr. The first deposition gas flow has about 0% to about 10% oxygen by concentration. The first perovskite film layer 503 is disposed via sputtering deposition from one or more targets, (e.g., a first target 304 and a second target 306). In one embodiment, the first target 304 is a coupled to an RF cathode 302A and the second target 306 is coupled to a DC/p-DC cathode 302B. In some embodiments, the targets 304, 306 may be metal targets or dielectric targets. In some embodiments, the first target 304 and the second target 306 may be formed of metals such as strontium (Sr), ruthenium (Ru), lanthanum (La), manganese (Mn), or a combination of both. In one embodiment, the first perovskite film layer 503 is a strontium ruthenium oxide or lanthanum strontium manganese oxide.

In one embodiment, the first perovskite film layer 503 is deposited using single target sputtering (e.g., the first target 304 or the second target 306). A shield 316 includes an opening 318 that is rotatably coupled to a chamber body adapter 308 of the multi-cathode processing chamber 300. The opening 318 can be selectively rotated using the actuator 324 between one or more targets, e.g., the first target 304 and the second target 306, to deposit the first perovskite film layer 503. For example, as shown in FIG. 3, the opening 318 may be selectively rotated to the first target 304 to expose the first target 304 to the substrate 336, while the second target 306 is housed within a pocket 320 of the shield 316 and is not exposed to the substrate 501. The first target 304 being exposed to the substrate 501 via the opening 318 allows for the first target 304 to deposit (e.g., sputter) material onto the substrate 501, while the shield 316 prevents the second target 306 from depositing (e.g., sputtering) material on to the substrate 501.

In another embodiment, the first perovskite film layer 503 is deposited using multi-target sputtering (e.g., co-sputtering) with two or more targets (e.g., the first target 304 and the second target 306). The shield 316 may include two or more openings 318 that can be selectively rotated between two or more targets, e.g., first target 304, and second target 306. For example, the multi-cathode processing chamber 300 may have three or more targets, e.g., first target 304, second target 306, and a third target (not shown). The shield 316 may be selectively rotated such that a first shield opening and a second shield opening expose the first target 304 and the second target 306 to the substrate, while the third target is housed within a pocket 320 of the shield 316 and is not exposed to the substrate. The first target 304 and second target 306 being exposed to the substrate 501 via the openings allows for the first target 304 and second target 306 to deposit (e.g., sputter) material onto the substrate 501, while the shield 316 prevents the third target from depositing (sputtering) material on to the substrate 501. In some embodiments, the co-sputtering technique may include one or more targets sputtering the same material. In other embodiments, the co-sputtering may include each target comprising a different material from the other targets. The ability to co-sputter two or more targets allows for greater control of the stoichiometry of the deposited perovskite film. The greater stoichiometric control over of the deposited perovskite film increases the crystallinity of the resultant perovskite film device.

In some embodiments, during the single target or the multi-target sputtering, the actuator 324 may rotate the substrate support to promote even deposition of the targets 304, 306. The actuator 324 may rotate the substrate support from about 5 rpm to about 90 rpm.

At optional operation 604, the material properties of the substrate 501 with the first perovskite film layer 503 disposed thereon may be measured at an on-board metrology station 118. The substrate 501 with the first perovskite film layer 503 disposed thereon may be transported to the on-board metrology station 118 from one of the processing chamber 103, 105, 107, 109, 110, 111, 112 using one of a first vacuum robot 130A with a first blade 134A in a first transfer chamber 136A or a second vacuum robot 130B with a second blade 134B in a second transfer chamber 136B of a cluster processing system 100.

At operation 605, a second perovskite film layer 504 is disposed over the first perovskite film layer 503 with a second deposition gas flow, as shown in FIG. 7C. The second deposition gas flow includes the process gas, which may include one of oxygen (O₂), argon (Ar), krypton (Kr), or neon (Ne). The second deposition gas flow is from about 0.1 mTorr to about 5 mTorr. The second deposition gas flow has about 0% to about 10% oxygen by concentration. In some embodiments, the second deposition gas flow is different from the first deposition gas flow. The second perovskite film layer 504 is disposed via sputtering deposition from one or more target, (e.g., the first target 304 and the second target 306). In one embodiment, the first target 304 is a coupled to the RF cathode 302A and the second target 306 is coupled to the DC/p-DC cathode 302B. In some embodiments, the targets 304, 306 may be metal targets or dielectric targets. In some embodiments, the first target 304 and the second target 306 may be formed of metals such as lanthanum (La), bismuth (Bi), iron (Fe), or a combination thereof. In one embodiment, the second perovskite film layer 504 is a lanthanum bismuth iron oxide.

In one embodiment, the second perovskite film layer 504 is deposited using single target sputtering (e.g., the first target 304 or the second target 306). The shield 316 includes the opening 318, which is rotatably coupled to a chamber body adapter 308 of the multi-cathode processing chamber 300. The opening 318 can be selectively rotated using the actuator 324 between one or more targets, e.g., the first target 304 and the second target 306, to deposit the second perovskite film layer 504. For example, as shown in FIG. 3, the opening 318 may be selectively rotated to the first target 304 to expose the first target 304 to the substrate 501, while the second target 306 is housed within a pocket 320 of the shield 316 and is not exposed to the substrate 501. The first target 304 being exposed to the substrate 501 via the opening 318 allows for the first target 304 to deposit (e.g., sputter) material onto the substrate 501, while the shield 316 prevents the second target 306 from depositing (e.g., sputtering) material on to the substrate 501.

In another embodiment, the second perovskite film layer 504 is deposited using multi-target sputtering (e.g., co-sputtering) with two or more targets (e.g., the first target 304 and the second target 306). The shield 316 may include two or more openings 318 that can be selectively rotated between two or more targets, e.g., first target 304, and second target 306. For example, the processing chamber may have three or more targets, e.g., first target 304, second target 306, and a third target (not shown). The shield 316 may be selectively rotated such that a first shield opening and a second shield opening expose the first target 304 and the second target 306 to the substrate 501, while the third target is housed within a pocket 320 of the shield 316 and is not exposed to the substrate 501. The first target 304 and second target 306 being exposed to the substrate 501 via the openings allows for the first target 304 and second target 306 to deposit (e.g., sputter) material onto the substrate 501, while the shield 316 prevents the third target from depositing (sputtering) material on to the substrate 501. In some embodiments, the co-sputtering technique may include one or more targets sputtering the same material. In other embodiments, the co-sputtering may include each target comprising a different material from the other targets. The ability to co-sputter two or more targets allows for greater control of the stoichiometry of the deposited perovskite film. The greater stoichiometric control over of the deposited perovskite film increases the crystallinity of the resultant perovskite film device.

At optional operation 606, the material properties of the substrate 501 with the second perovskite film layer 504 disposed thereon may be measured at an on-board metrology station 118. The substrate 501 with the second perovskite film layer 504 disposed thereon may be transported to the on-board metrology station 118 from one of the processing chamber 103, 105, 107, 109, 110, 111, 112 using one of a first vacuum robot 130A with a first blade 134A in a first transfer chamber 136A or a second vacuum robot 130B with a second blade 134B in a second transfer chamber 136B of a cluster processing system 100.

At operation 607, a third perovskite film layer 505 is disposed over the second perovskite film layer 504 with a third deposition gas flow, as shown in FIG. 7D. The third deposition gas flow includes the process gas, which may include one of oxygen (O₂), argon (Ar), krypton (Kr), or neon (Ne). The third deposition gas flow is from about 0.1 mTorr to about 5 mTorr. The third deposition gas flow has about 0% to about 10% oxygen by concentration. In some embodiments, the third deposition gas flow is different from the first deposition gas flow and the second deposition gas flow. The third perovskite film layer 505 is disposed via sputtering deposition from one or more target, (e.g., the first target 304 and the second target 306). In one embodiment, the first target 304 is a coupled to the RF cathode 302A and the second target 306 is coupled to the DC/p-DC cathode 302B. In some embodiments, the targets 304, 306 may be metal targets or dielectric targets. In some embodiments, the first target 304 and the second target 306 may be formed of metals such as strontium (Sr), ruthenium (Ru), lanthanum (La), manganese (Mn), or a combination of both. In one embodiment, the third perovskite film layer 505 is strontium ruthenium oxide or lanthanum strontium manganese oxide.

In one embodiment, the third perovskite film layer 505 is deposited using single target sputtering (e.g., the first target 304 or the second target 306). The shield 316 including the opening 318 is rotatably coupled to a chamber body adapter 308 of the multi-cathode processing chamber 300. The opening 318 can be selectively rotated using the actuator 324 between one or more targets, e.g., the first target 304 and the second target 306, to deposit the third perovskite film layer 505. For example, as shown in FIG. 3, the opening 318 may be selectively rotated to the first target 304 to expose the first target 304 to the substrate 501, while the second target 306 is housed within a pocket 320 of the shield 316 and is not exposed to the substrate 501. The first target 304 being exposed to the substrate 501 via the opening 318 allows for the first target 304 to deposit (e.g., sputter) material onto the substrate 501, while the shield 316 prevents the second target 306 from depositing (e.g., sputtering) material on to the substrate 501.

In another embodiment, the third perovskite film layer 505 is deposited using multi-target sputtering (e.g., co-sputtering) with two or more targets (e.g., the first target 304 and the second target 306). The shield 316 may include two or more openings 318 that can be selectively rotated between two or more targets, e.g., first target 304, and second target 306. For example, the multi-cathode processing chamber 300 may have three or more targets, e.g., first target 304, second target 306, and a third target (not shown). The shield 316 may be selectively rotated such that a first shield opening and a second shield opening expose the first target 304 and the second target 306 to the substrate 501, while the third target is housed within a pocket 320 of the shield 316 and is not exposed to the substrate 501. The first target 304 and second target 306 being exposed to the substrate 501 via the openings allows for the first target 304 and second target 306 to deposit (e.g., sputter) material onto the substrate 501, while the shield 316 prevents the third target from depositing (sputtering) material on to the substrate. In some embodiments, the co-sputtering technique may include one or more targets sputtering the same material. In other embodiments, the co-sputtering may include each target comprising a different material from the other targets. The ability to co-sputter two or more targets allows for greater control of the stoichiometry of the deposited perovskite film. The greater stoichiometric control over of the deposited perovskite film increases the crystallinity of the resultant perovskite film device.

At optional operation 608, the material properties of the substrate 501 with the third perovskite film layer 505 disposed thereon may be measured at an on-board metrology station 118. The substrate 501 with the third perovskite film layer 505 disposed thereon may be transported to the on-board metrology station 118 from one of the processing chamber 103, 105, 107, 109, 110, 111, 112 using one of a first vacuum robot 130A with a first blade 134A in a first transfer chamber 136A or a second vacuum robot 130B with a second blade 134B in a second transfer chamber 136B of a cluster processing system 100.

At operation 609, the substrate 501 with the seed layer 502, first perovskite film layer 503, second perovskite film layer 504, and third perovskite film layer 505 disposed thereon is annealed to form a perovskite film device 500. The substrate 501 is transported to the annealing chamber 124 in the load lock chamber 122 using the first blade 134A of the first vacuum robot 130A or the second blade 134B of the second vacuum robot 130B, depending on which processing chamber 103, 105, 107, 109, 110, 111, 112 is in use. In one embodiment, the annealing occurs in controlled ambient conditions. The annealing is performed at a controlled temperature ramp rate within the load lock chamber 122. By annealing the perovskite films disposed on the substrate, the crystallinity of the perovskite film device 500 is promoted.

At operation 610, the perovskite film device 500 is lithographed and etched. The lithography and etching exposes the second perovskite film layer 504 to create a top electrode and capacitor dielectric layer. The lithography and etching exposes the first perovskite film layer 503 to create a bottom electrode. The lithography and etching exposes seed layer 502 to create an electrode for the perovskite film device 500. In some embodiments, the lithography includes a bi-layer (photoresist and bottom anti-reflective coating (BARC)) or tri-layer (photoresist, BARC, and hard mask) can be used to define the structure to be formed. In some embodiments, the etching may be chlorine-based, fluorine-based, or argon-based reactive ion etching. In other embodiments, a mixture of chlorine, fluorine, and argon may be used for reactive ion etching.

In summary, methods and processing systems for fabricating perovskite thin film devices are shown herein. The perovskite film layers that form the perovskite thin film device are deposited using a multi-cathode deposition chamber. The multi-cathode deposition allows for greater stoichiometric control over the perovskite film layers and increases the crystallinity of the resultant perovskite film device. The multi-cathode deposition chamber includes one or more targets. One of the one or more targets is coupled to an RF power source. The impedance and capacitance of the RF power source can be controlled to enable the correct amount of power to be delivered to the target. The perovskite film layers are annealed to further improve the crystallinity of the resultant perovskite film device. On-board metrology stations within the processing system allow for measuring the material properties of the perovskite film devices during the processing of the perovskite film layers.

While the foregoing is directed to embodiments of the present disclosure, other and further embodiments of the disclosure may be devised without departing from the basic scope thereof, and the scope thereof is determined by the claims that follow.

What is claimed is:

1. A method of fabricating a perovskite film device, comprising:
heating and degassing a substrate within a processing system;
depositing a perovskite film layer over a surface of the substrate using multi-cathode sputtering deposition within a processing chamber; and
annealing the substrate with the perovskite film layer disposed thereon.

2. The method of claim 1, further comprising measuring a thickness and one or more material properties of the perovskite film layer at an on-board metrology station within the processing system.

3. The method of claim 1, wherein the processing chamber includes a plurality of targets and a shield, wherein the shield is operable to selectively expose one or more of the plurality of targets and selectively prevent one or more of the plurality of targets from sputtering.

4. The method of claim 3, wherein the processing chamber includes a first target and a second target, the first target comprising a first material and the second target comprising a second material, the second material being different from the first material, wherein the shield exposes the first target and second target during the multi-cathode sputtering deposition.

5. The method of claim 4, wherein the first material comprises one of strontium (Sr), ruthenium (Ru), lanthanum (La), manganese (Mn), or a combination of thereof and the second material comprises one or lanthanum (La), bismuth (Bi), iron (Fe), or a combination thereof.

6. The method of claim 4, wherein one of the first target or the second target is coupled to an RF cathode and an RF matching network.

7. The method of claim 4, wherein the first material and the second material comprise one of strontium (Sr), ruthenium (Ru), lanthanum (La), manganese (Mn), bismuth (Bi), iron (Fe), or a combination thereof.

8. The method of claim 3, wherein the processing chamber includes a first target and a second target, the first target comprising a first material and the second target comprising a second material, the second material being the same as the first material, wherein the shield exposes the first target and second target during the multi-cathode sputtering deposition.

9. A method of fabricating a perovskite film device, comprising:
heating and degassing a substrate within a processing system;
depositing a first perovskite film layer over a surface of the substrate using multi-cathode sputtering deposition within a processing chamber, wherein the first perovskite film layer comprises a first perovskite material;
depositing a second perovskite film layer over the first perovskite film layer using multi-cathode sputtering deposition within a processing chamber, wherein the second perovskite film layer comprises a second perovskite material; and
annealing the substrate with the first perovskite film layer and second perovskite film layer disposed thereon.

10. The method of claim 9, further comprising measuring a thickness and one or more material properties of the first perovskite film layer and second perovskite film layer at an on-board metrology station within the processing system.

11. The method of claim 9, wherein the second perovskite material is different from the first perovskite material.

12. The method of claim 11, wherein the first perovskite material is one of strontium ruthenium oxide or lanthanum strontium manganese oxide and the second perovskite material is lanthanum bismuth iron oxide.

13. The method of claim 9, wherein the second perovskite material is the same as the first perovskite material.

14. The method of claim 9, further comprising depositing a third perovskite film layer over the second perovskite film layer using multi-cathode sputtering deposition, wherein the third perovskite film layer comprises a third perovskite material.

15. The method of claim 14, wherein the third perovskite material is different from both the first perovskite material and the second perovskite material.

16. The method of claim 14, wherein the third perovskite material is the same as either the first perovskite material or the second perovskite material.

17. A method of fabricating a perovskite film device, comprising:
depositing a seed layer on a substrate;
depositing a first perovskite film layer over the seed layer;
depositing a second perovskite film layer over the first perovskite film layer;
depositing a third perovskite film layer over the second perovskite film layer;
annealing the substrate and perovskite film layers;
lithographing and etching the second perovskite film layer and third perovskite film layer to form a top electrode and capacitor dielectric layer; and
lithographing and etching the first perovskite film layer to form a bottom electrode.

18. The method of claim 17 wherein the first perovskite film layer and the third perovskite film layer comprise one of strontium ruthenium oxide or lanthanum strontium manganese oxide and the second perovskite film layer comprises lanthanum bismuth iron oxide.

19. The method of claim 17, wherein the first perovskite film layer and third perovskite film layer are deposited using co-sputtering from a first target and a second target.

20. The method of claim 19, wherein the first target and the second target comprise one of strontium (Sr), ruthenium (Ru), lanthanum (La), manganese (Mn), bismuth (Bi), iron (Fe), or a combination thereof.
